(19) United States
(12) Patent Application Publication
(10) Pub. No.: US 2014/0284687 A1
(43) Pub. Date: Sep. 25, 2014

(54) NONVOLATILE MEMORY DEVICE AND METHOD FOR MANUFACTURING SAME

(71) Applicant: KABUSHIKI KAISHA TOSHIBA, Minato-ku (JP)

(72) Inventor: Sadatoshi MURAKAMI, Kanagawa-ken (JP)

(73) Assignee: KABUSHIKI KAISHA TOSHIBA, Minato-ku (JP)

(21) Appl. No.: 13/971,170

(22) Filed: Aug. 20, 2013

(30) Foreign Application Priority Data
Mar. 25, 2013 (JP) 2013-063104

(51) Int. Cl. H01L 27/115; H01L 23/535

(52) U.S. Cl. CPC H01L 27/11578; H01L 23/535
USPC 257/324; 438/586

(57) ABSTRACT

According to one embodiment, a nonvolatile memory device includes a plurality of electrodes provided on an under layer and arranged in parallel to the under layer, a semiconductor layer piercing one of the electrodes in the first direction, a memory film provided between the one of the electrodes and the semiconductor layer, and a bridge portion provided between the electrodes adjacent to each other. Each of the electrodes including a plurality of first layers having conductivity and a plurality of second layers having insulation properties, the first layers being stacked in a first direction perpendicular to the under layer, and each of the second layers being provided between the first layers adjacent to each other.

### CROSS-REFERENCE TO RELATED APPLICATIONS

This application is based upon and claims the benefit of priority from Japanese Patent Application No. 2013-063104, filed on Mar. 25, 2013; the entire contents of which are incorporated herein by reference.

### FIELD

Embodiments described herein relate generally to a nonvolatile memory device and a method for manufacturing the same.

### BACKGROUND

Nonvolatile memory devices such as NAND flash memories are manufactured by using a semiconductor wafer process. Increasing memory capacity, reducing power consumption, and reducing manufacturing cost thereof have been realized as advancing the two-dimensional miniaturization technologies in the wafer process. However, enormous capital investment may be necessary for further evolution of fine processing technology. Thus, the memory devices are under development, which have the three-dimensional structure including a plurality of memory layers.

### BRIEF DESCRIPTION OF THE DRAWINGS

FIG. 1 is a perspective view schematically showing a nonvolatile memory device according to a first embodiment;

FIG. 2 is a schematic sectional view showing the nonvolatile memory device according to the first embodiment;

FIGS. 3A to 9B are schematic views showing a manufacturing process of a nonvolatile memory device according to the first embodiment;

FIGS. 10A to 13C are schematic views showing a manufacturing process of a nonvolatile memory device according to a variation of the first embodiment; and

FIGS. 14A to 18C are schematic views showing a manufacturing process of a nonvolatile memory device according to a second embodiment.

### DETAILED DESCRIPTION

According to one embodiment, a nonvolatile memory device includes a plurality of electrodes provided on an under layer and arranged in parallel to the under layer, a semiconductor layer piercing one of the electrodes in the first direction, a memory film provided between the one of the electrodes and the semiconductor layer, and a bridge portion provided between the electrodes adjacent to each other. Each of the electrodes including a plurality of first layers having conductivity and a plurality of second layers having insulation properties, the first layers being stacked in a first direction perpendicular to the under layer, and each of the second layers being provided between the first layers adjacent to each other.

Various embodiments will be described hereinafter with reference to the accompanying drawings. Like portions in the drawings are labeled with like reference numerals, with the detailed description thereof omitted appropriately, and the different portions are described. The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

### First Embodiment

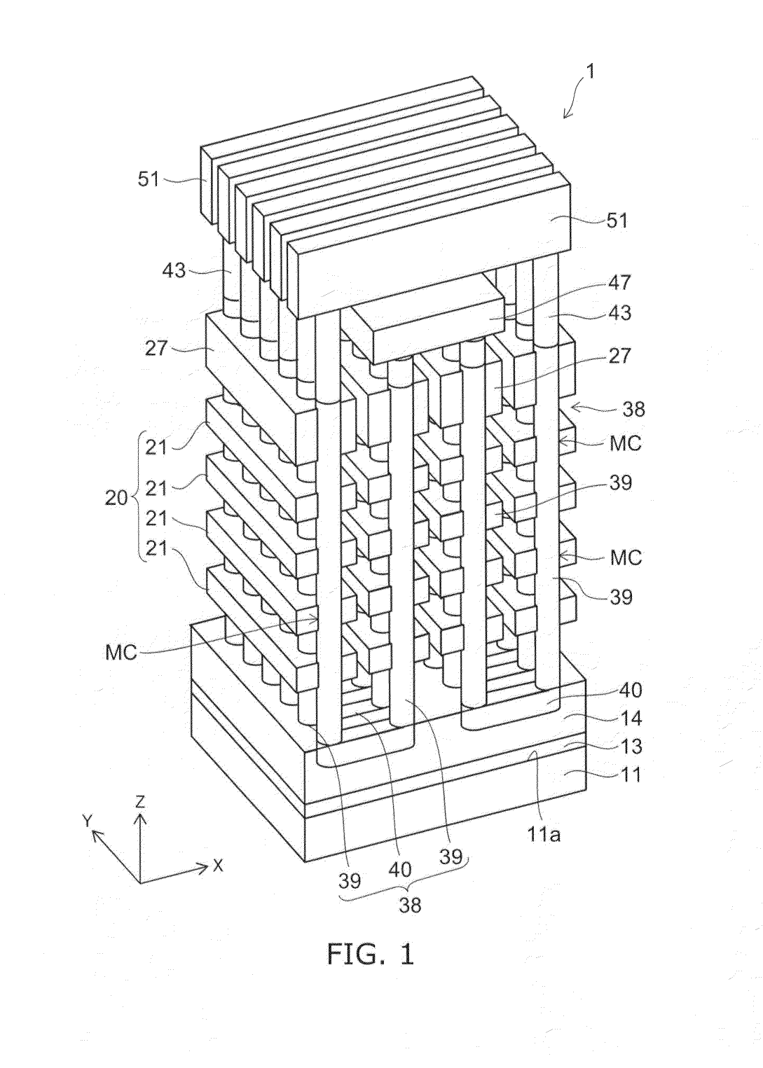

FIG. 1 is a perspective view schematically showing a nonvolatile memory device according to a first embodiment.

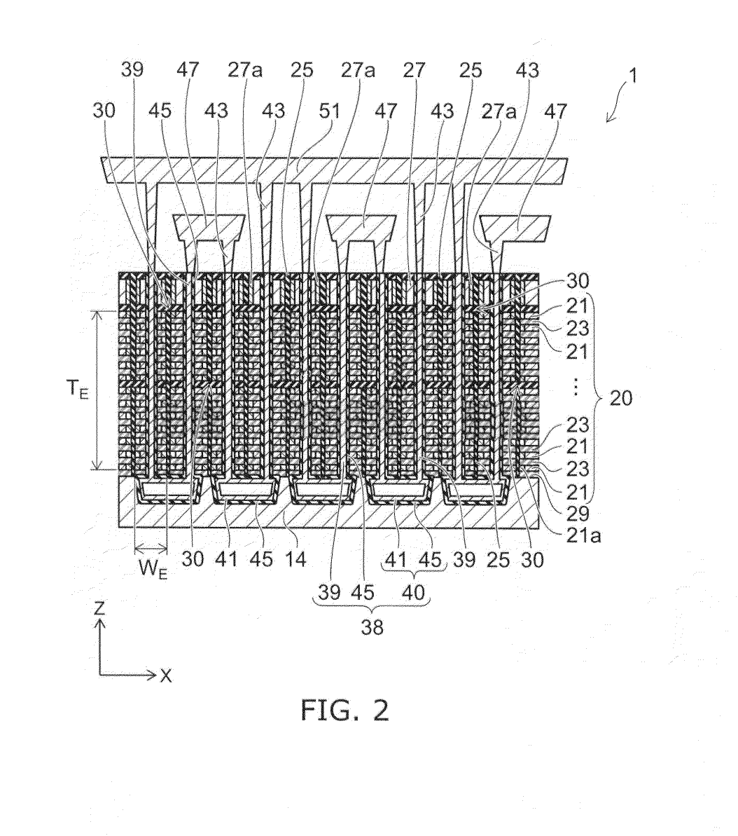

FIG. 2 is a schematic sectional view showing the nonvolatile memory device according to the first embodiment.

The nonvolatile memory device according to the embodiment is so called a NAND flash memory, and includes a three-dimensional memory cell array 1. FIG. 1 is a perspective view showing part of the memory cell array 1. In FIG. 1, insulating layers are not shown to facilitate understanding the structure. That is, the components of the memory cell array 1 are insulated from each other by the insulating layers (not shown).

As shown in FIG. 1, the nonvolatile memory device includes a memory cell array 1 provided on an under layer.

The under layer is e.g. a substrate 11. The substrate 11 is e.g. a silicon substrate. In the upper surface 11a of the substrate, a circuit is provided for controlling the memory cell array 1. An interlayer insulating film 13 is provided on the substrate 11. The memory cell array 1 is provided on the interlayer insulating film 13.

The memory cell array 1 includes a conductive layer 14 provided on the interlayer insulating film 13, a stacked electrode 20 provided on the conductive layer 14, a select gate 27 provided on the stacked electrode 20, a source line 47 provided on the select gate 27, and a bit line 51 provided on the source line 47.

In the following, the direction perpendicular to the substrate 11 is referred to as Z direction. One of the two directions orthogonal to the Z direction is referred to as X direction and the other is referred to as Y direction. In some cases, the Z direction is expressed as upward, and the opposite is expressed as downward.

The stacked electrode 20 provided on the conductive layer 14 includes a plurality of control gates 21. The control gate 21 is provided like a stripe extending in the Y direction. A plurality of stacked electrodes 20 are provided in the X direction, and arranged in parallel to a substrate 11.

The select gate 27 extends in the Y direction, and is provided on each stacked electrode 20. Furthermore, a semiconductor layer 39 piercing the stacked electrode 20 and the select gate 27 in the Z direction is provided.

Pair of the semiconductor layers 39 is electrically connected by a joining portion 40. The one of the pair pierces any one of the stacked electrodes 20 adjacent to each other, and the other of the pair pierces other one of the stacked electrodes. The upper ends of the semiconductor layers 39 are electrically connected to the source line 47 and the bit line 51, respectively, via plugs 43. That is, the memory cell string 38 provided between the source line 47 and the bit line 51 includes two semiconductor layers 39 and a joining portion 40 connecting therebetween.

A memory film 45 (see FIG. 2) is provided on the outer surface of the semiconductor layer 39 and the joining portion 40. The memory film 45 provided between the semiconductor layer 39 and the control gate 21 serves as a charge storage film. That is, a memory cell MC is provided between each control gate 21 and the semiconductor layer 39. Furthermore, a select transistor is provided between the select gate and the semiconductor layer 39. The memory film 45 also serves as a gate insulating film thereof. The memory film 45 provided on the joining portion 40 electrically insulates between the joining portion 40 and the conductive layer 14.

As shown in FIG. 2, the semiconductor layer 39 is provided like e.g. a column extending in the Z direction. The outer surface thereof is covered with the memory film 45. The joining portion 40 includes e.g. a conductive layer 41 having a hollow structure. The memory film 45 is provided on the outer surface thereof. The semiconductor layer 39 and the conductive layer 41 are e.g. polycrystalline silicon (polysilicon) layers having conductivity, and are electrically connected to each other.

As described later, the semiconductor layer 39 is provided inside a hole piercing the stacked electrode 20 and the select gate 27. For instance, the semiconductor layer 39 is formed by depositing a polysilicon layer on the memory film 45 that is formed on the inner surface of the through hole. The semiconductor layer 39 may have a columnar structure filling the through hole, or a hollow structure having an unfilled space therein.

An insulating layer 29 is provided on the conductive layer 14, and the stacked electrode 20 is provided thereon. The stacked electrode 20 includes control gates 21 and insulating layers 23 alternately stacked on each other. The control gate 21 is a conductive first layer, such as a polysilicon film. The insulating layer 23 is a second layer having insulation properties, and includes e.g. at least one of silicon oxide and silicon nitride.

A plurality of stacked electrodes 20 are provided and arranged in parallel on the conductive layer 14. Furthermore, an insulating film 25 (third insulating film) is provided therebetween. The insulating film 25 includes e.g. at least one of silicon oxide and silicon nitride. A silicide portion 21a is provided on the portion of the control gate 21 in contact with the insulating film 25. The insulating film 25 extends also between select gates 27, each of which is provided on the stacked electrode 20. A silicide portion 27a is provided on the portion of the select gate 27 in contact with the insulating film 25. The silicide portions 21a and 27a reduce the gate resistance of the control gate 21 and the select gate 27, respectively.

Furthermore, a bridge portion 30 is provided between the stacked electrodes 20. The two adjacent stacked electrodes 20 support each other via the bridge portion 30. This may prevent the stacked electrode 20 from collapse.

For instance, the number of memory cells MC included in one memory cell string 38 can be increased as increasing the stacking number of the control gates 21. This may increase the memory capacity (the amount of information stored per unit area) of the memory cell array 1. On the other hand, the width W_{E} in the X direction of the stacked electrode 20 may be narrowed to e.g. a size near the limit of fine processing in the wafer process. Thus, when the stacked number of the control gates 21 is increased, it makes the height T_{E} of the stacked electrode 20 higher, and the aspect ratio (T_{E}/W_{E}) is made higher. As a result, the stacked electrode 20 may collapse in the manufacturing process of the memory cell array 1.

For instance, the end portion of the control gate 21 and the select gate 27 is silicidized via an air gap provided between the stacked electrodes 20. In this process, if the aspect ratio of the stacked electrode 20 is made higher, the possibility of its collapse is increased. In contrast, in the embodiment, the adjacent stacked electrodes 20 support each other via the bridge portion 30 provided therebetween. This may prevent collapse of the stacked electrode 20, and improve the manufacturing yield.

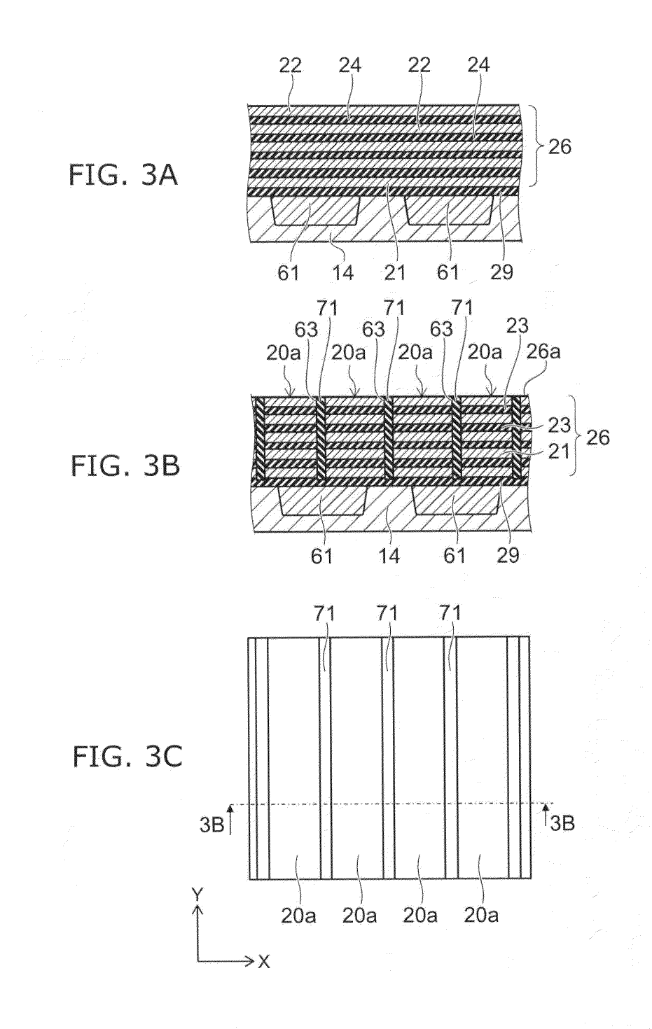

Next, with reference to FIGS. 3A to 9B, a method for manufacturing a nonvolatile memory device according to the embodiment is described. FIGS. 3A to 9B are schematic views showing a process for manufacturing a nonvolatile memory device according to the first embodiment.

FIG. 3A is a schematic view showing a cross section of a first stacked body 26 provided on the conductive layer 14. The first stacked body 26 includes first layers 22 and second layers 24 stacked alternately in the Z direction. The first layer 22 is conductive, and the second layer 24 is non-conductive. The first layer 22 is e.g. a polysilicon layer having conductivity. The second layer 24 is e.g. a silicon oxide layer.

Alternatively, the second layer 24 may be e.g. a polysilicon layer without doping impurity. In such a case, the second layers 24 are selectively removed and the removed portions are replaced with an insulating layer.

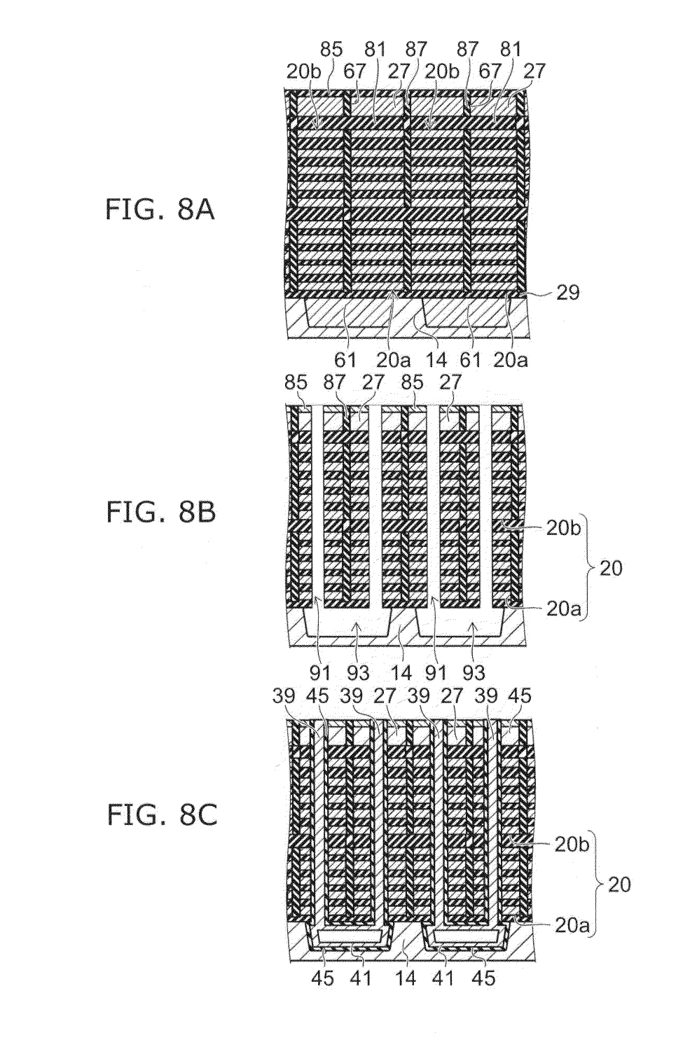

As shown in FIG. 3A, the conductive layer 14 includes a sacrificial film 61. In the process described later (see FIG. 8B), the sacrificial film 61 will be selectively etched, and a joining portion 40 will be provided in that portion. Furthermore, between the conductive layer 14 and the first stacked body 26, an insulating layer 29 is provided. The insulating layer 29 has etching selectivity with respect to the first layer 22 and the second layer 24. The insulating layer is not etched nor has less etching rate, while selectively etching the first layers and the second layers for making the slits between the stacked electrodes. The insulating layer 29 may include e.g. tantalum oxide (TaO_{X}).

FIG. 3B is a sectional view of the first stacked body 26 taken along line 3B-3B shown in FIG. 3C. FIG. 3C is a plan view showing the upper surface of the first stacked body 26.

As shown in FIG. 3B, the first stacked body 26 is divided into a plurality of first stacked electrodes 20a. Specifically, slits 63 (first slits) are formed from the upper surface 26a of the first stacked body 26 to the insulating layer 29, and sacrificial films 71 (first sacrificial film) are embedded in the slits 63 respectively.

For instance, a sacrificial film is formed inside the slits 63 and on the first stacked body 26. Then, the portion formed on the first stacked body 26 is removed by using e.g. etch-back or CMP (chemical mechanical polishing) technique, leaving the portions formed inside the slits 63.

The sacrificial films 71 have etching selectivity with respect to the first layers 22 and the second layers 24. For instance, when each first layer 22 includes polysilicon, and each second layer 24 includes silicon oxide, the sacrificial film 71 may include silicon nitride.

Each slit 63 is formed to a depth dividing the first stacked body 26, but not reaching the conductive layer 14. To this end, an insulating layer 29 having etching selectivity with respect to the first layer 22 and the second layer 24 is provided between the first stacked body 26 and the conductive layer 14. That is, an etching condition not etching the insulating layer 29, or etching the insulating layer 29 at a slower etching rate, is used when etching the first layer 22 and the second layer 24. Thus, the etching of the slits 63 may be stopped at the insulating layer 29.

As shown in FIG. 3C, the first stacked electrode 20a is formed like a stripe extending in the Y direction. The first stacked electrode 20a includes a plurality of control gates 21, which are formed by dividing the first layers 22, and a plurality of insulating layers 23, which are formed by dividing the second layer 24. Each control gate 21 and each insulating layer 23 are alternately stacked. The number of stacked layers is limited so as to avoid collapse of the stacked electrode 20a. That is, the stacking number of the control gates 21 is preferably limited to suppress the aspect ratio, so as to avoid the collapse of the first stacked electrode 20a while forming the slits 63.

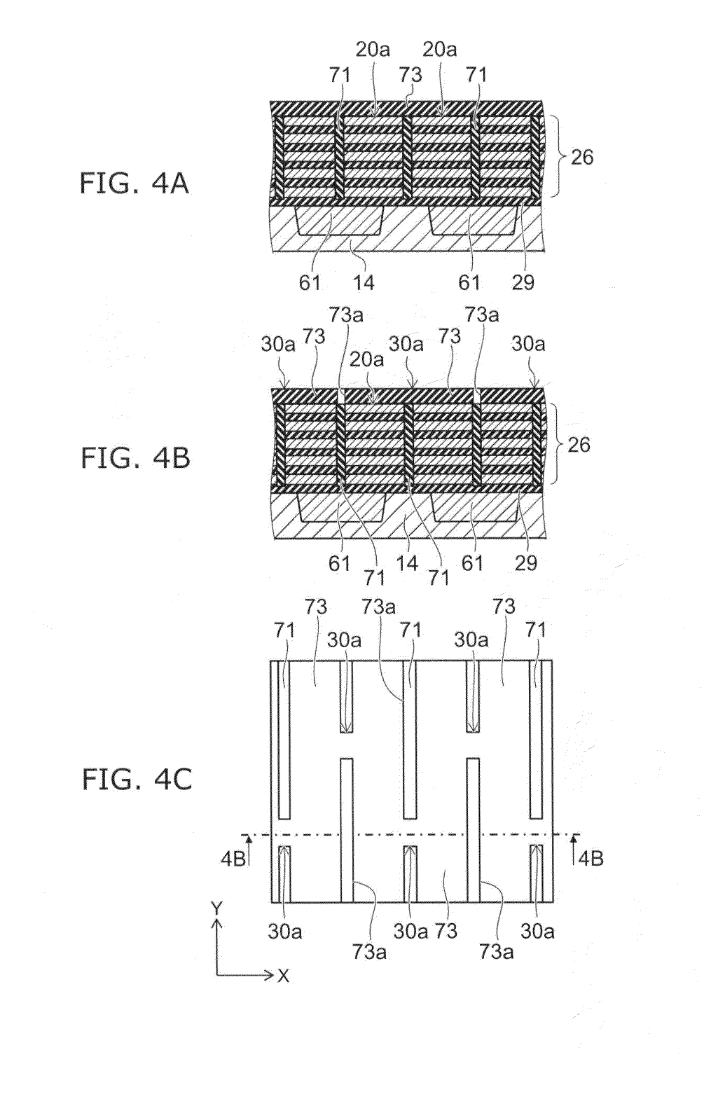

FIGS. 4A and 4B are sectional views taken along line 4B-4B shown in FIG. 4C. FIGS. 4A and 4B show a manufacturing process subsequent to FIG. 3B. FIG. 4C is a plan view showing the upper surface of the first stacked body 26.

As shown in FIG. 4A, an insulating layer 73 (first bridge layer) is formed on the first stacked electrodes 20a and the sacrificial films 71. The insulating layer 73 may be one of the second layers 24 insulating the control gates 21, and includes a bridge portion 30. For instance, when the sacrificial film 71 is a silicon nitride film, the insulating layer 73 may be formed using silicon oxide.

Next, as shown in FIG. 4B, the insulating layer 73 is selectively etched to form an opening 73a communicating with the sacrificial film 71, using photo-lithography.

As shown in FIG. 4C, the insulating layer 73 is patterned into a stripe covering each first stacked electrode 20a. A bridge portion 30a is provided between the insulating layers 73 adjacent to each other. That is, the striped openings 73a are formed to be in communication with the sacrificial films 71, respectively. Each opening 73a extending in the Y direction is divided by the bridge portion 30a provided on the sacrificial film 71.

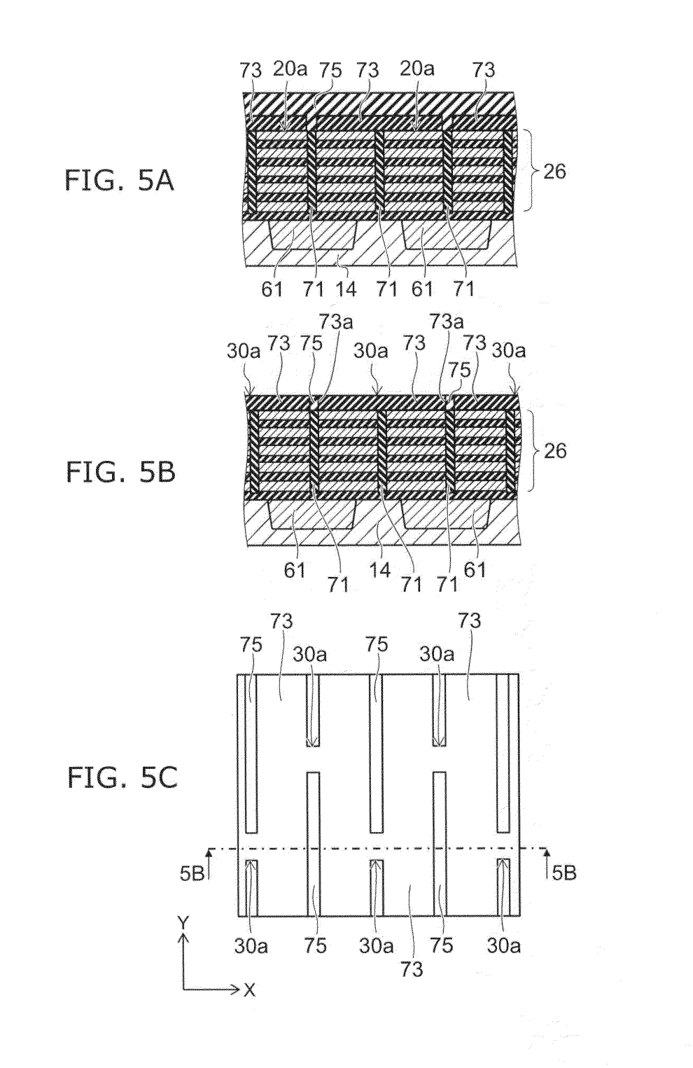

FIGS. 5A and 5B are sectional views taken along line 5B-5B shown in FIG. 5C. FIGS. 5A and 5B show a manufacturing process subsequent to FIG. 4B. FIG. 5C is a plan view showing the upper surface of the first stacked body 26.

As shown in FIG. 5A, a sacrificial film 75 is formed on the insulating layer 73 and inside the openings 73a. The sacrificial film 75 is e.g. a silicon nitride film.

Next, as shown in FIG. 5B, for instance, the sacrificial film 75 formed on the insulating layer 73 is removed by using etch-back or CMP (chemical mechanical polishing) technique, leaving the portions embedded in the openings 73a. That is, the surface of the insulating layer 73 and the surface of the sacrificial film 75 embedded in the opening 73a are planarized. As shown in FIG. 5C, the sacrificial film 75 is embedded inside the opening 73a provided in the insulating layer 73.

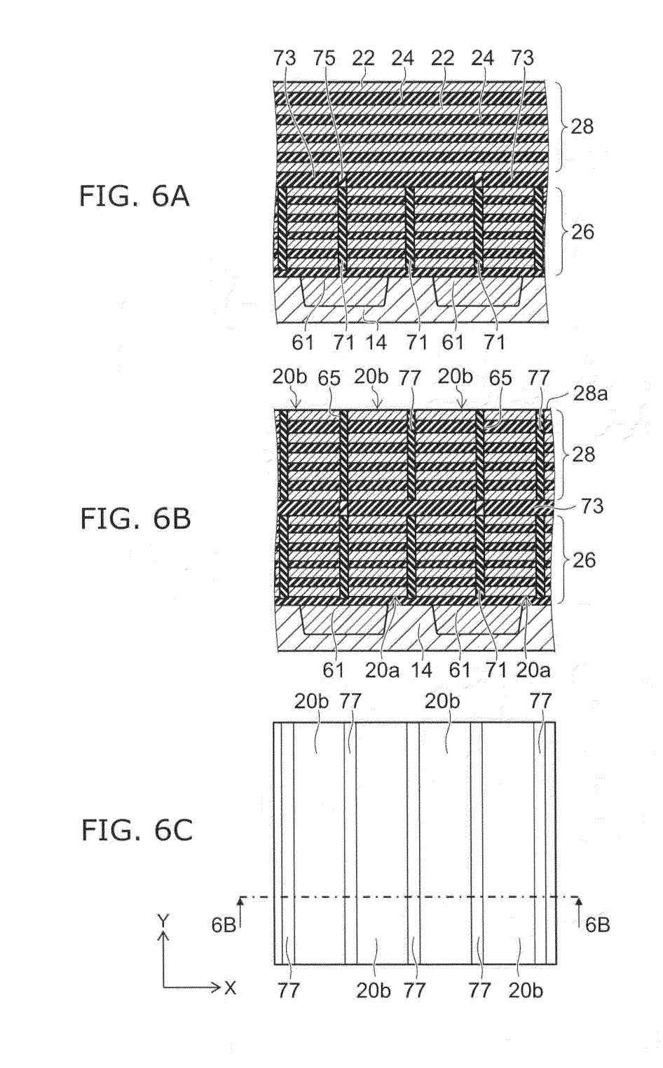

FIGS. 6A and 6B are sectional views taken along line 6B-6B shown in FIG. 6C. FIGS. 6A and 6B show a manufacturing process subsequent to FIG. 5B. FIG. 6C is a plan view showing the upper surface of a second stacked body 28 provided on the first stacked body 26.

As shown in FIG. 6A, a second stacked body 28 is formed on the insulating layer 73. The second stacked body 28 includes first layers 22 and second layers 24. Each first layer 22 is e.g. a conductive polysilicon layer. Each second layer 24 includes e.g. silicon oxide. Each first layers 22 and each second layers 24 are alternately stacked. The stacking number of respective layers is preferably limited to suppress an aspect ratio in the range capable of avoiding collapse of the stacked electrode 20.

Next, as shown in FIG. 6B, slits 65 (second trench) are formed from the upper surface 28a of the second stacked body 28, so as to communicate with the sacrificial films 75. Then, sacrificial films 77 (second sacrificial film) are embedded inside the slits 65 respectively. Each sacrificial film 77 is e.g. a silicon nitride film. Thus, the second stacked body 28 is divided into a plurality of second stacked electrodes 20b.

As shown in FIG. 6C, the second stacked electrode 20b is formed like a stripe extending in the Y direction. The second stacked electrode 20b is provided on the first stacked electrode 20a.

For instance, the stacking number of the first layers 22 and the second layers 24 included in the second stacked body 28 is preferably limited to suppress an aspect ratio of the second stacked electrode 20b in the range preventing its collapse. This may avoid the collapse of the second stacked electrode 20b, while forming the slit 65.

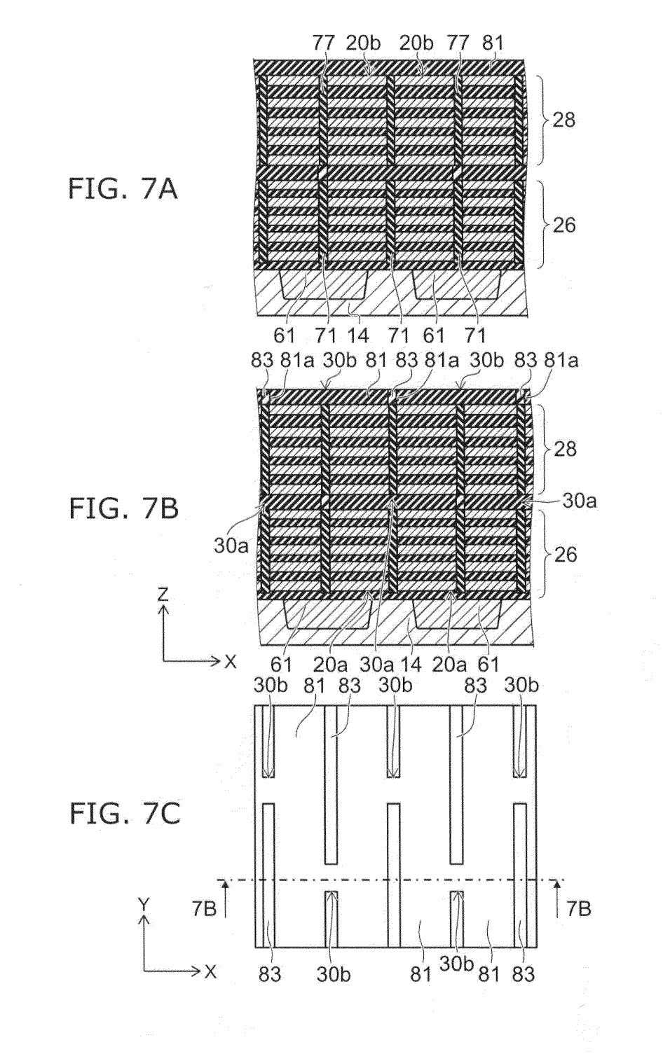

FIGS. 7A and 7B are sectional views taken along line 7B-7B shown in FIG. 7C. FIGS. 7A and 7B show a manufacturing process subsequent to FIG. 6B. FIG. 7C is a plan view showing the upper surface of the second stacked body 28.

As shown in FIG. 7A, an insulating layer 81 (second bridge layer) is formed on the second stacked electrode 20b and on the sacrificial films 77. The insulating layer 81 may be one of second layers 24 insulating the control gates 21, and includes a bridge portion 30b. The insulating layer 81 is e.g. a silicon oxide film. Next, the insulating layer 81 is selectively etched using a lithography process to form openings 81a communicating with the sacrificial films 77 respectively.

Next, as shown in FIG. 7B, sacrificial films 83 are formed inside the openings 81a. Each sacrificial film 83 is e.g. a silicon nitride film, and is formed by the same method described in FIGS. 5A and 5B. That is, the sacrificial film 83 formed on the insulating layer 81 is removed by using etch-back or CMP technique, leaving the portions embedded in the openings 81a.

As shown in FIG. 7C, the insulating layer 81 is patterned into a stripe covering the second stacked electrodes 20b. The sacrificial films 83 are embedded inside the openings 81a provided between the adjacent stripes. The sacrificial film 83 extending in the Y direction is divided by the bridge portion 30b provided on the sacrificial film 77. Furthermore, as shown in FIG. 7B, the bridge portion 30b is provided at a position not overlapping the bridge portion 30a in the Z direction.

FIGS. 8A to 8C are sectional views showing a manufacturing process subsequent to FIG. 7B.

As shown in FIG. 8A, select gates 27 are formed on the insulating layer 81. Each select gate 27 is formed on any one of the second stacked electrode 20b. A sacrificial film 87 is embedded between the adjacent select gates 27. Furthermore, an insulating layer 85 may be provided on the select gates 27.

That is, a conductive polysilicon layer is formed on the insulating layer 81 and the sacrificial film 83, for instance. From its upper surface, openings 67 are formed, each of which is in communication with the sacrificial film 83. Then, sacrificial films 87 are embedded inside the openings 67 respectively. Each sacrificial film 87 is e.g. a silicon nitride film.

Next, as shown in FIG. 8B, through holes 91 are formed extending from the upper surface of the insulating layer 85 to the conductive layer 14. Then, the sacrificial layers 61 are etched via the through holes 91 to form joining holes 93. Each joining hole 93 is connected to the ends of the through holes 91 formed in the adjacent stacked electrodes 20.

Next, as shown in FIG. 8C, a memory film 45 is formed on the inner surface in each of the through holes 91 and the joining holes 93. The memory film 45 is e.g. a multilayer film in which a silicon oxide film and a silicon nitride film are alternately stacked. Next, a conductive layer 41 is formed on the memory film 45 provided on the inner surface of the joining hole 93, and a semiconductor layer 39 is formed on the memory film 45 in the through hole 91. The semiconductor layer 39 and the conductive layer 41 are simultaneously formed including conductive polysilicon, for example. That is, the polysilicon layer is formed inside the through hole 91 and the joining hole 93 communicating with each other, using e.g. reduced pressure CVD (chemical vapor deposition) technique. The deposition of the polysilicon layer formed inside the joining hole 93 may be stopped when the through hole 91 is occluded with the polysilicon layer. That is, an unfilled space may generate inside the joining hole 93.

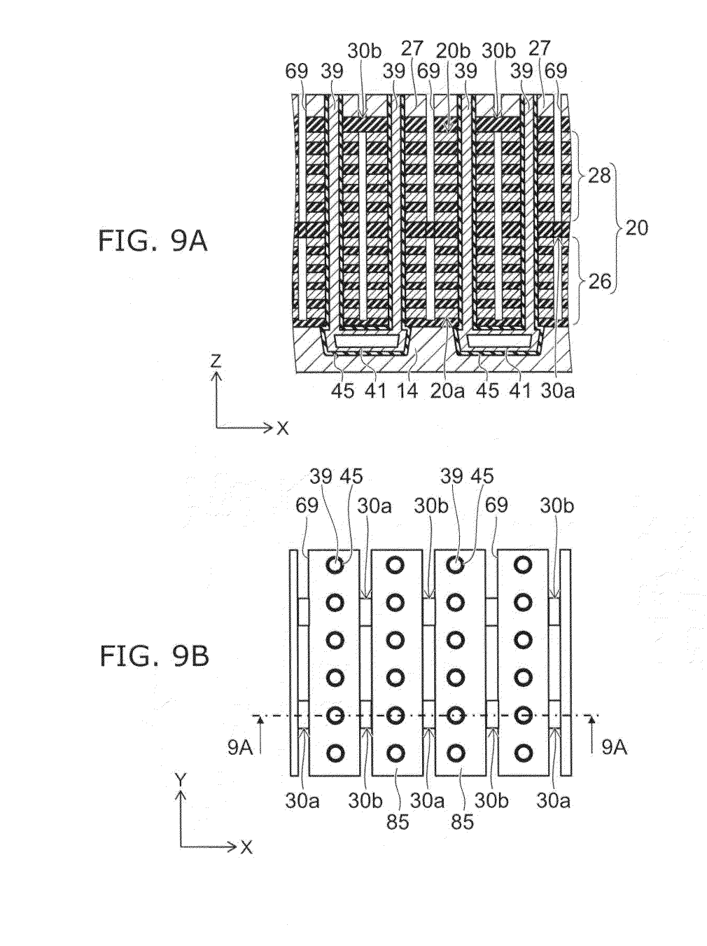

FIGS. 9A and 9B are sectional views showing a manufacturing process subsequent to FIG. 8C. FIG. 9A is a sectional view taken along line 9A-9A shown in FIG. 9B. FIG. 9B is a plan view showing the upper surface of the select gate 27.

As shown in FIG. 9A, the sacrificial films 71, 75, 77, 83, and 87 are selectively etched to form slits 69 between the stacked electrodes 20. That is, the sacrificial films are etched so as to expose the end portions of the first stacked electrode 20a, the second stacked electrode 20b, and the select gate 27. Next, the inner surface of the slits 69 is covered with a metal film made of e.g. nickel. Then, heat treatment is performed. Thus, each end portion of the control gates 21 and the select gates 27 is silicidized.

As shown in FIG. 9B, the bridge portions 30a and 30b are formed between the stacked electrodes 20. This enables the adjacent stacked electrodes 20 to support each other. For instance, when all the sacrificial films are removed in the process of silicidation, it may be possible to avoid the collapse of the stacked electrodes 20. Specifically, this may prevent the stacked electrodes 20 from the collapse, during the washing and drying steps after the silicidation.

The insulating layer 73 (first bridge layer) providing the bridge portion 30a and the insulating layer 81 (second bridge layer) providing the bridge portion 30b may be formed thicker than the insulating layer 23. Then, even if part of the insulating layers 73 and 81 is etched in the process of etching the sacrificial films 71, 75, 77, 83, and 87, the bridge layers 30a and 30b can be left between the adjacent stacked electrodes 20.

Furthermore, in the manufacturing method illustrated above, the second stacked electrode 20b is stacked on the first stacked electrode 20a. The embodiment is not limited thereto. For instance, the process of FIGS. 6A to 7B may be repeated to increase the stacking number of the control gates 21. Then, even if the aspect ratio of the stacked electrode 20 is increased as increasing the stacking number of the control gates 21, the bridge portions 30 may prevent the collapse.

Furthermore, the bridge portions 30 are provided at positions not overlapping each other in the Z direction. This may facilitate etching the sacrificial films 71, 75, 77, 83, and 87.

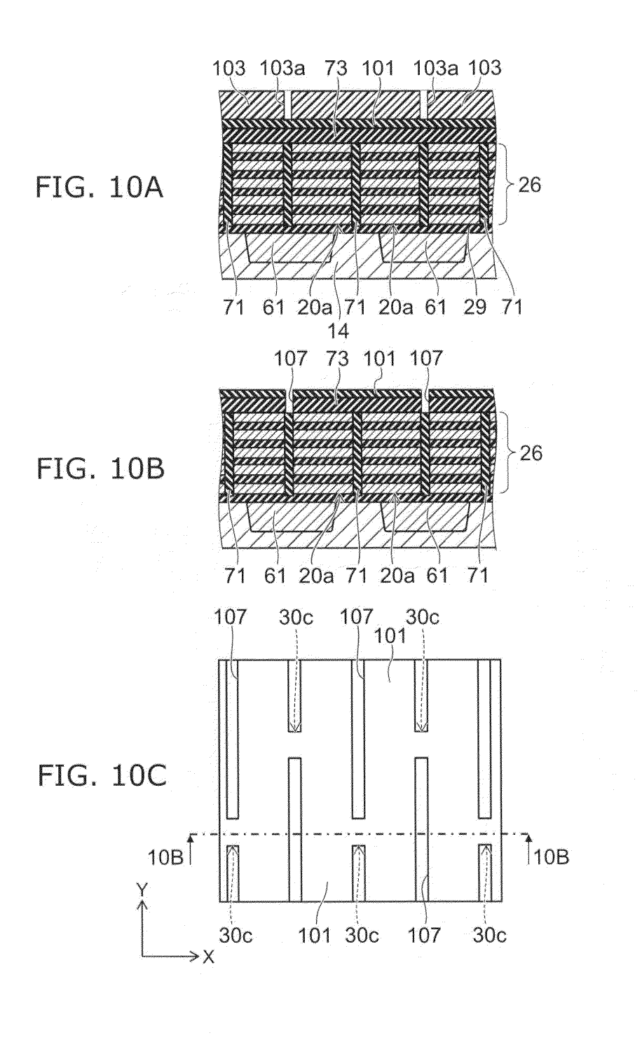

Next, with reference to FIGS. 10A to 13C, a method for manufacturing a nonvolatile memory device according to a variation of the embodiment is described. FIGS. 10A to 13C are schematic views showing a manufacturing process according to the variation of the first embodiment.

FIGS. 10A and 10B are schematic views showing a manufacturing process subsequent to FIG. 4A. FIGS. 10A and 10B are sectional views taken along line 10B-10B shown in FIG. 10C. FIG. 10C is a plan view showing the upper surface of the first stacked body 26.

As shown in FIG. 10A, an insulating layer 73 (first insulating layer) is formed on the first stacked body 26. Then, an insulating layer 101 (second insulating layer) is provided on the insulating layer 73. That is, the first bridge layer in the variation includes the insulating layer 73 and the insulating layer 101.

For instance, when the insulating layer 73 is the silicon oxide film, and the sacrificial film 71 is the silicon nitride film, part of the insulating layer 73 is etched in the process of etching the sacrificial film 71. Thus, an insulating layer 101 is formed on the insulating layer 73, which has a slower etching rate than the insulating layer 73 under the etching condition of the sacrificial film 71. This may suppress etching of the insulating layer 73. The insulating layer 101 is e.g. a tantalum oxide film.

Next, an etching mask 103 is formed on the insulating layer 101 using a photo-lithography process. The etching mask 103 is e.g. a resist film and includes openings 103a.

Next, as shown in FIG. 10B, the etching mask 103 is used to selectively etch the insulating layer 101 and the insulating layer 73. Thus, openings 107 are formed in communication with the sacrificial films 71 respectively.

As shown in FIG. 10C, the insulating layer 73 and the insulating layer 101 are patterned into a stripe covering the first stacked electrodes 20a. A bridge portion 30c is provided between the striped insulating layers adjacent to each other. That is, striped openings 107 are formed in communication with the sacrificial film 71. Each opening 107 extending in the Y direction is divided by the bridge portion 30c provided on the sacrificial film 71.

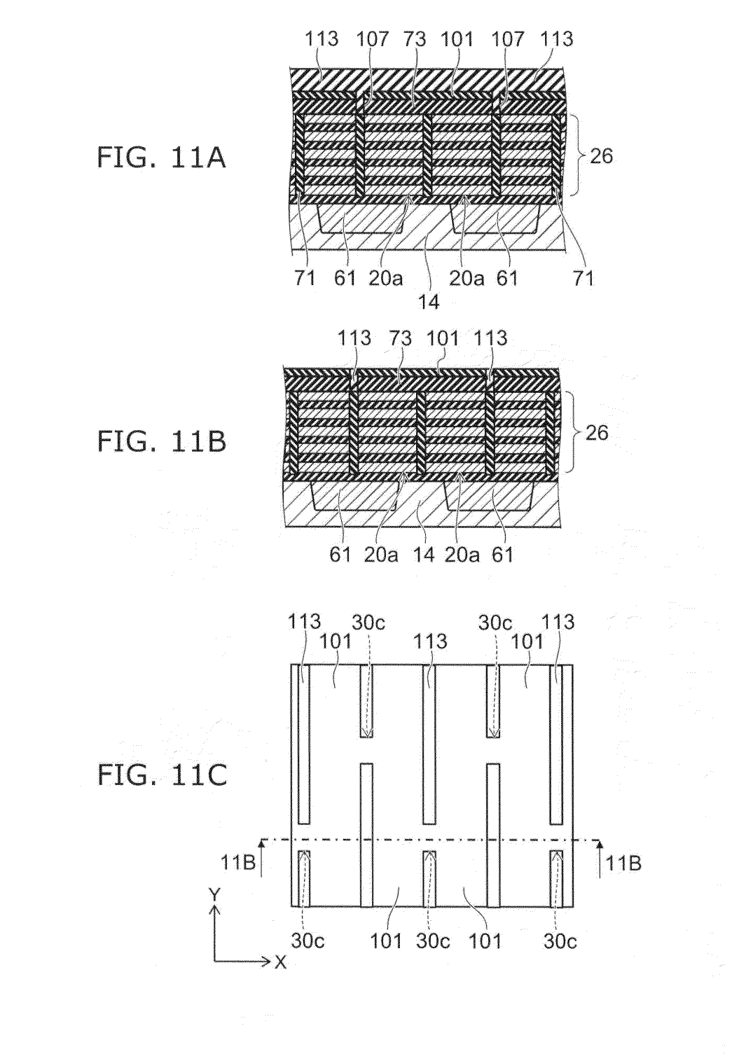

FIGS. 11A and 11B are sectional views taken along line 11B-11B shown in FIG. 11C. FIGS. 11A and 11B show a manufacturing process subsequent to FIG. 10B. FIG. 11C is a plan view showing the upper surface of the first stacked body 26.

As shown in FIG. 11A, a sacrificial film 113 is formed on the insulating layer 101 and inside the openings 107. The sacrificial film 113 is e.g. a silicon nitride film.

Next, as shown in FIG. 11B, the sacrificial film 113 formed on the insulating layer 101 is removed by using e.g. etch-back or CMP technique, leaving the portions embedded inside the openings 107. That is, the surface of the sacrificial film 113 embedded in the openings 107 is planar zed to be the same level as the surface of the insulating layer 101. As shown in FIG. 11C, the sacrificial films 113 are embedded inside the openings 107 piercing the insulating layer 101 and the insulating layer 73 and communicating with the sacrificial film 71.

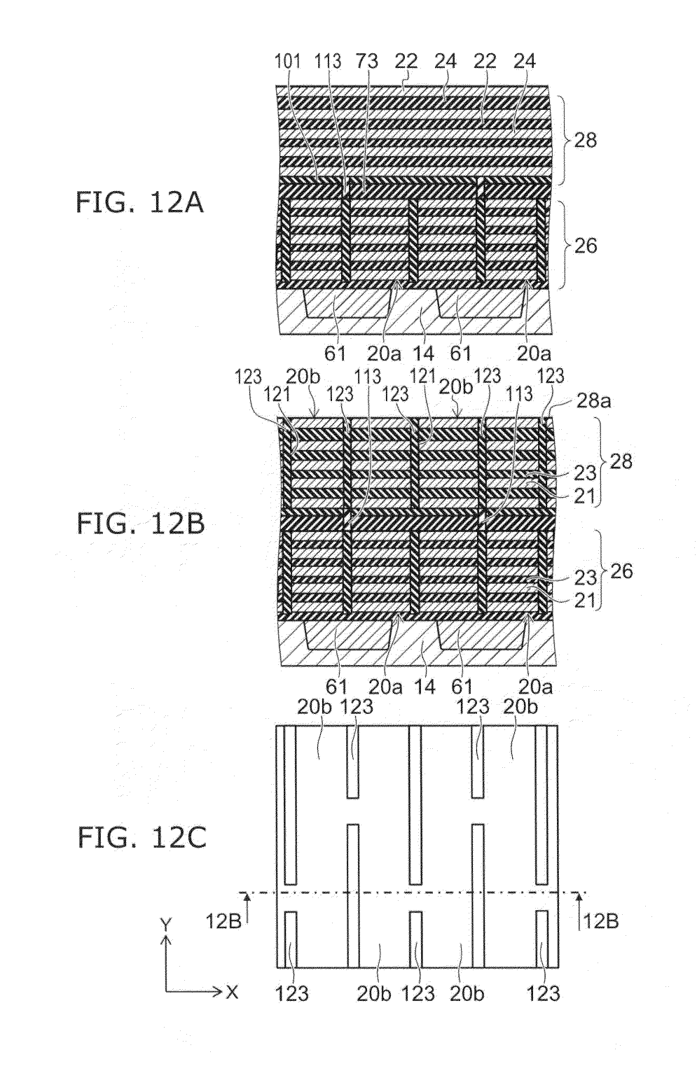

FIGS. 12A and 12B are sectional views taken along line 12B-12B shown in FIG. 12C. FIGS. 12A and 12B show a manufacturing process subsequent to FIG. 11B. FIG. 12C is a plan view showing the upper surface of a second stacked body 28 provided on the first stacked body 26.

As shown in FIG. 12A, a second stacked body 28 is formed on the insulating layer 101. The second stacked body 28 includes first layers 22 and second layers 24. Each first layer 22 is e.g. a conductive polysilicon layer. Each second layer 24 is e.g. a silicon oxide layer. Each first layer 22 and each second layer 24 are alternately stacked on the insulating layer 101. The stacking number of respective layers is preferably limited to suppress the aspect ratio of the stacked electrode 20 in the range of avoiding the collapse.

Next, as shown in FIG. 12B, slits 121 are formed from the upper surface 28a of the second stacked body 28 so as to be in communication with the sacrificial films 113 respectively. Then, sacrificial films 123 are embedded inside the slits 121. The sacrificial film 123 is e.g. a silicon nitride film. Thus, the second stacked body 28 is divided into a plurality of second stacked electrodes 20b.

As shown in FIG. 12C, the second stacked electrode 20b is formed like a stripe extending in the Y direction. The second stacked electrode 20b is provided on the first stacked electrode 20a. For instance, the stacking number of the control gates 21 (first layers 22) and the insulating films 23 (second layers 24) included in the second stacked body 28 is limited to suppress the aspect ratio of the second stacked electrode 20b in the range of avoiding the collapse. This can prevent the second stacked electrode 20b from the collapse, while forming the slit 121.

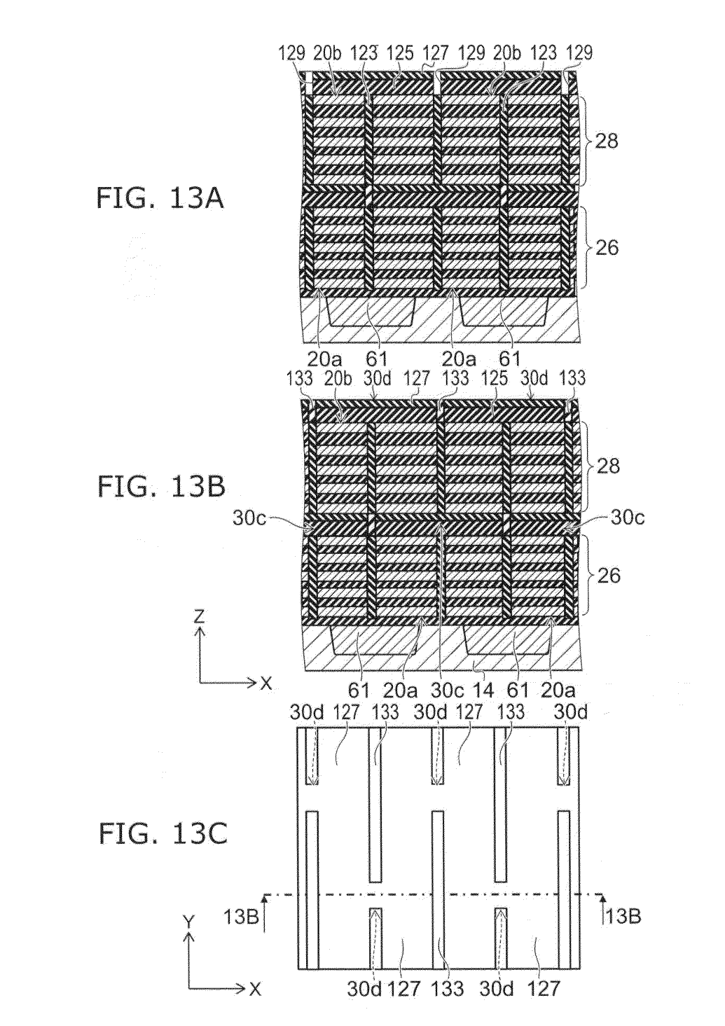

FIGS. 13A and 13B are sectional views taken along line 13B-13B shown in FIG. 13C. FIGS. 13A and 13B show a manufacturing process subsequent to FIG. 12B. FIG. 13C is a plan view showing the upper surface of the second stacked body 28.

As shown in FIG. 13A, an insulating layer 125 is formed on the second stacked electrode 20b and on the sacrificial films 123. Furthermore, an insulating layer 127 is formed thereon. That is, the second bridge layer includes the insulating layer 125 and the insulating layer 127. The insulating layer 125 is e.g. a silicon oxide film. The insulating layer 127 is e.g. a tantalum oxide film. Next, the insulating layer 125 and the insulating layer 127 are selectively etched to form openings 129 communicating with the sacrificial films 123 respectively, using a lithography process.

Next, as shown in FIG. 13B, a sacrificial film 133 is formed inside the openings 129. The sacrificial film 133 is e.g. a silicon nitride film, and is formed by the same method as the process described in FIGS. 5A and 5B. That is, the sacrificial film 133 formed on the insulating layer 127 is removed using etch-back or CMP technique, leaving the portions embedded inside the openings 129.

As shown in FIG. 13C, the insulating layers 125 and 127 are patterned into a stripe covering the second stacked electrodes 20b. The sacrificial film 133 is embedded in the openings 129 provided between the adjacent stripes. Each sacrificial film 133 extending in the Y direction is divided by the bridge portion 30d provided on the sacrificial film 123. Furthermore, as shown in FIG. 13B, the bridge portion 30d is provided at a position not overlapping the bridge portion 30c in the Z direction.

Thus, in the variation, the first bridge layer and the second bridge layer include parts of the first insulating layer and the second insulating layer provided thereon. The second insulating layer suppresses etching of the first insulating layer in the process of etching the sacrificial films. Thus, the first insulating layer may be formed to have a thickness e.g. equal to or thinner than the thickness of the second layer (the insulating layer 23).

### Second Embodiment

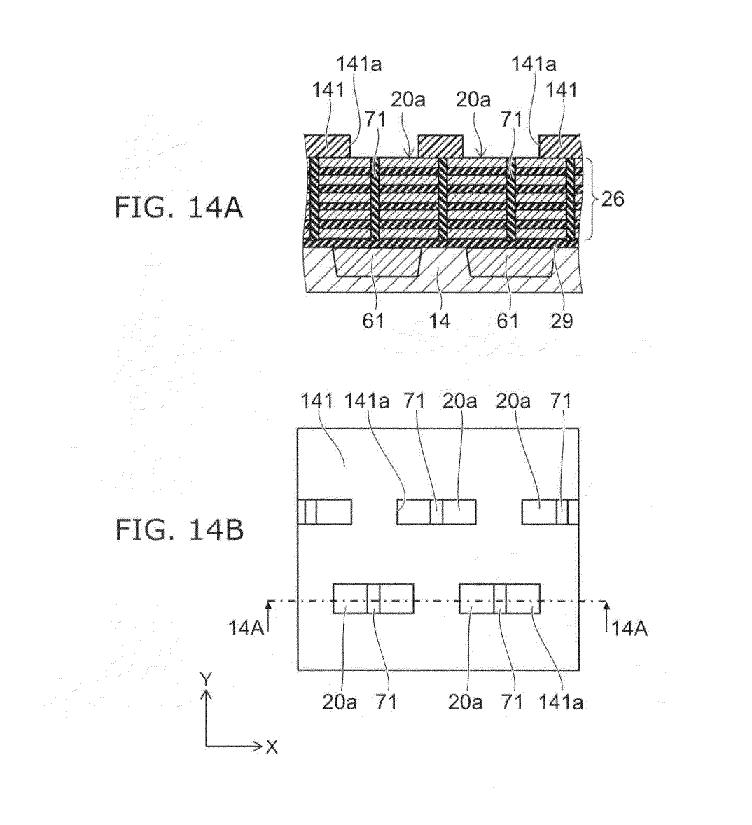

Next, with reference to FIGS. 14A to 18C, a method for manufacturing a nonvolatile memory device according to a second embodiment is described. FIGS. 14A to 18C are schematic views showing a process for manufacturing a nonvolatile memory device according to the second embodiment.

FIG. 14A is a schematic view showing a manufacturing process subsequent to FIG. 3B. FIG. 14A is a sectional view taken along line 14A-14A shown in FIG. 14B. FIG. 14B is a plan view showing the upper surface of the first stacked body 26.

As shown in FIG. 14A, an etching mask 141 is formed on the first stacked body 26. The etching mask 141 is e.g. a resist mask, and includes openings 141a, each of which includes a region for forming a bridge portion. That is, as shown in FIG. 14B, part of the sacrificial film 71 is exposed at the bottom surface of the opening 141a, and parts of the first stacked electrodes 20a are exposed on both sides of the exposed sacrificial film 71.

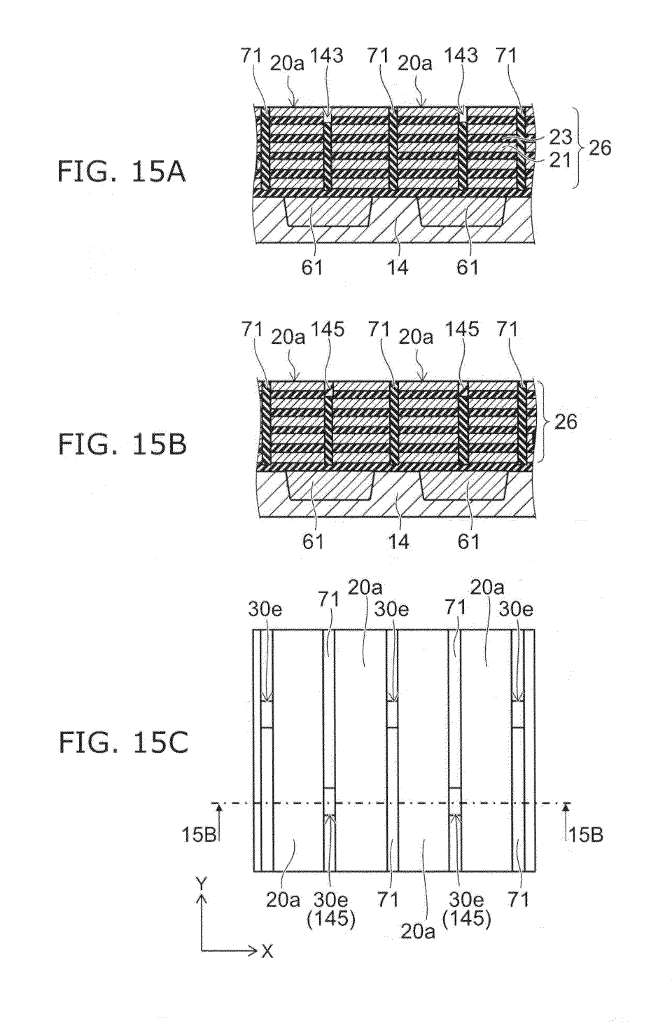

FIGS. 15A and 15B are sectional views taken along line 15B-15B shown in FIG. 15C. FIGS. 15A and 15B show a manufacturing process subsequent to FIG. 14A. FIG. 15C is a plan view showing the upper surface of the first stacked body 26.

The etching mask 141 shown in FIGS. 14A and 14B is used to partly etch back the sacrificial film 71. Thus, as shown in FIG. 15A, a recess 143 is formed in each opening 141a on the upper surface of the first stacked body 26. The sacrificial film 71 is etched under a condition of e.g. not etching the control gate 21 and the insulating layer 23 included in the first stacked electrode 20a, or a condition of etching them at a slower etching rate than a rate for the sacrificial film 71. Thus, the upper surface of the first stacked electrode 20a may be exposed in the opening 141a of the etching mask 141. That is, the alignment accuracy of the region for forming a bridge portion can be relaxed so as to facilitate the manufacturing process.

Next, as shown in FIG. 15B, insulators are embedded in the recesses 143 to form bridge portions 30e. Each bridge portion 30e is a member different from the sacrificial film 71. In the example, the bridge portion 30e is formed embedding an insulating film 145. The insulating film 145 is e.g. a silicon oxide film, and is formed on the first stacked electrode 20a and inside the recess 143. Then, the portion formed on the first stacked electrodes 20a is removed by etch-back or CMP technique, leaving the portions embedded in the recesses 143.

As shown in FIG. 15C, the bridge portion 30e is provided between the striped first stacked electrodes 20a extending in the Y direction. The bridge portions 30e are provided at staggered positions, i.e., the bridge portions 30e arranged in the X direction are provided at positions alternately shifted in the Y direction.

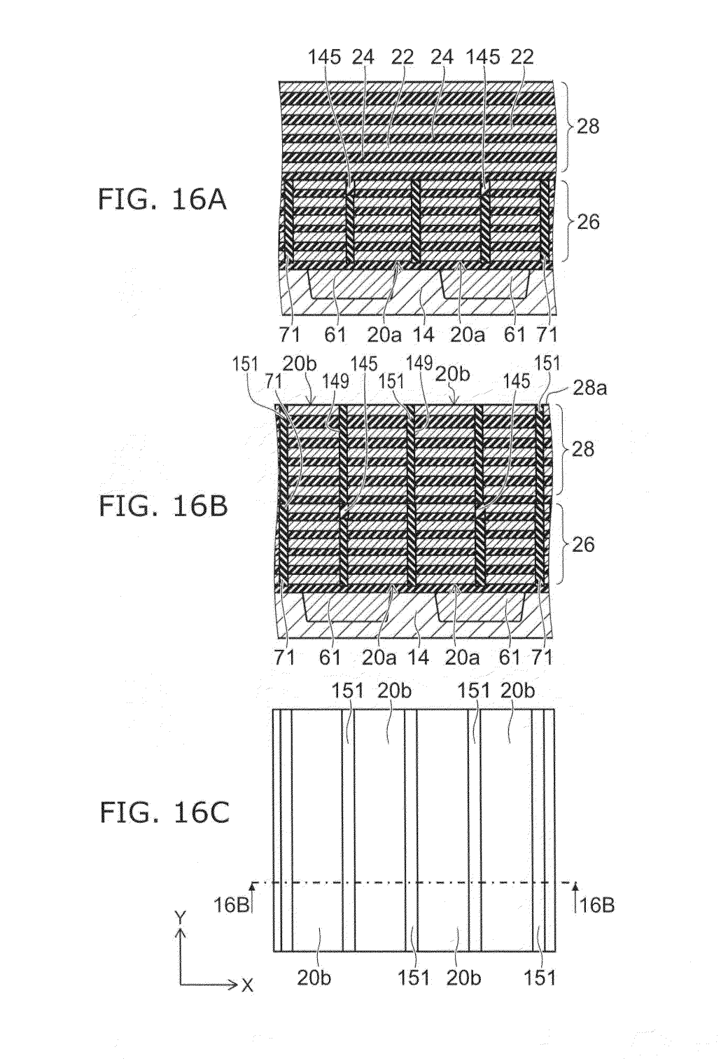

FIGS. 16A and 16B are sectional views taken along line 16B-16B shown in FIG. 16C. FIGS. 16A and 16B show a manufacturing process subsequent to FIG. 15B. FIG. 16C is a plan view showing the upper surface of a second stacked body 28 provided on the first stacked body 26.

As shown in FIG. 16A, a second stacked body 28 is formed on the first stacked body 26 in which the bridge portion 30e has been formed. The second stacked body 28 includes first layers 22 and second layers 24. Each first layer 22 is e.g. a conductive polysilicon film. Each second layer 24 is e.g. a silicon oxide film. The first layers 22 and the second layers 24 are alternately stacked on the first stacked body 26. The stacking number of respective layers is preferably limited to suppress the aspect ratio of the stacked electrode 20 in the range of avoiding the collapse.

Next, as shown in FIG. 16B, slits 149 are formed from the upper surface 28a of the second stacked body 28 so as to be in communication with the sacrificial films 71 respectively. Then, sacrificial films 151 are embedded inside the slits 149. Each sacrificial film 151 is e.g. a silicon nitride film. Thus, the second stacked body 28 is divided into a plurality of second stacked electrodes 20b.

As shown in FIG. 16C, the second stacked electrode 20b is formed like a stripe extending in the Y direction. The second stacked electrode 20b is provided on the first stacked electrode 20a. For instance, the stacking number of the first layers 22 and the second layers 24 included in the second stacked body 28 is limited to suppress the aspect ratio of the second stacked electrode 20b in the range of avoiding the collapse. This may prevent the second stacked electrode 20b from the collapse, while forming the slits 149.

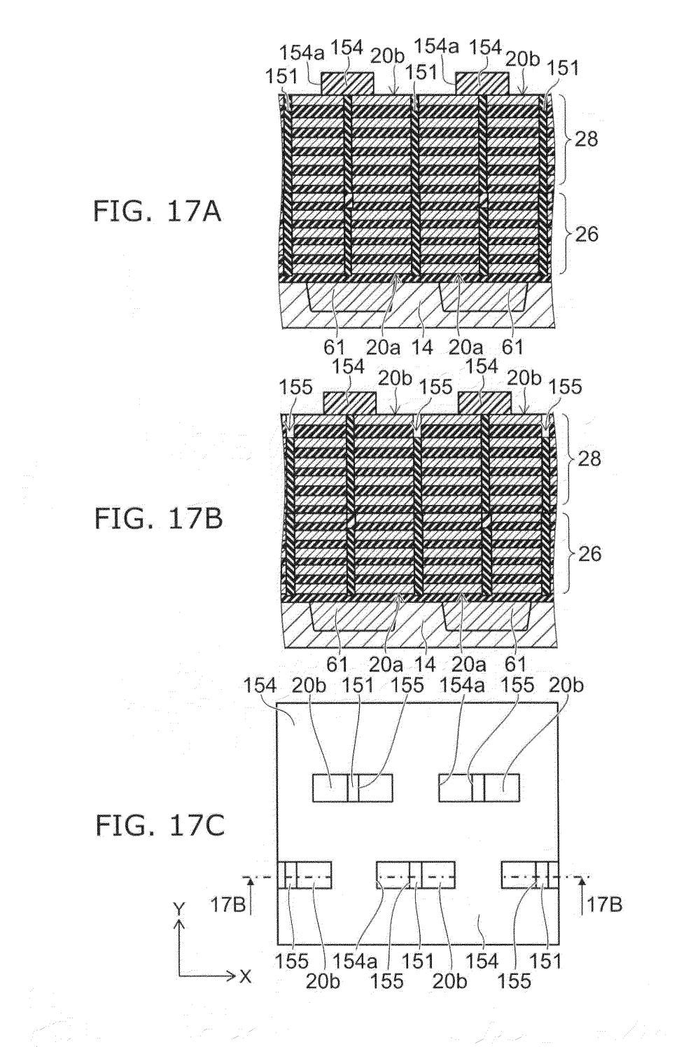

FIGS. 17A and 17B are sectional views taken along line 17B-17B shown in FIG. 17C. FIGS. 17A and 17B show a manufacturing process subsequent to FIG. 16B. FIG. 17C is a plan view showing the upper surface of the second stacked body 28 provided on the first stacked body 26.

As shown in FIG. 17A, an etching mask 154 is formed on the second stacked body 28. The etching mask 154 is e.g. a resist mask, and includes openings 154a, each of which includes a region for forming a bridge portion. That is, as shown in FIG. 17C, part of the sacrificial film 151 is exposed at each bottom surface of the openings 154a, and parts of the second stacked electrodes 20b also exposed on both sides thereof.

Next, as shown in FIG. 17B, the etching mask 154 is used to partly etch back the sacrificial films 151. Thus, a recess 155 is formed in each opening 154a on the upper side of the second stacked body 28.

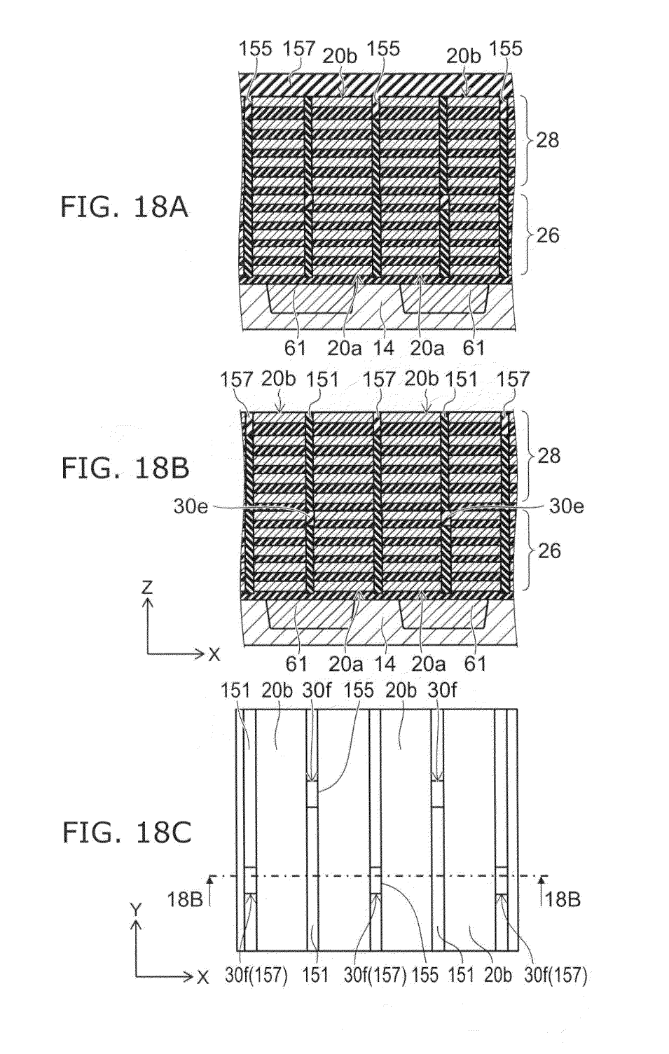

FIGS. 18A and 18B are sectional views taken along line 18B-18B shown in FIG. 18C. FIGS. 18A and 18B show a manufacturing process subsequent to FIG. 17B. FIG. 18C is a plan view showing the upper surface of the second stacked body 28.

As shown in FIG. 18A, an insulating film 157 is formed on the second stacked body 28. The insulating film 157 is e.g. a silicon oxide film. The insulating film 157 is formed on the second stacked body 28 and embedded inside the recesses 155.

Next, the insulating film 157 formed on the second stacked electrode 20b is removed by etch-back or CMP technique. As shown in FIG. 18B, the portions embedded inside the recess 155 is left.

As shown in FIG. 18C, each insulating film 157 embedded inside the recess 155 forms a bridge portion 30f. The bridge portion 30f is provided between the striped second stacked electrodes 20b extending in the Y direction. The bridge portion 30f is provided at a position not overlapping the bridge portion 30e in the Z direction. That is, the bridge portions 30f are provided at staggered positions having phase shift in the X direction from the bridge portions 30e.

Next, the memory cell array 1 can be completed through the process shown in FIGS. 8A to 9B. Also in the embodiment, the bridge portions 30e and 30f are formed between the stacked electrodes 20. This enables the adjacent stacked electrodes 20 to support each other. Thus, when all the sacrificial films 71 and 151 are removed, it may be possible to avoid the collapse of the stacked electrodes 20. For instance, this can prevent the stacked electrode 20 from the collapse during the washing and drying steps after silicidation.

The thickness in the Z direction of the insulating films 145 and 157 forming the bridge portions 30e and 30f, respectively, can be controlled by the depth, i.e., the amount of etch-back, of the recesses 143 and 155. The insulating films 145 and 157 may be provided thicker than e.g. the insulating layer 23. Thus, even if the insulating films 145 and 157 are etched in the process of etching the sacrificial films 71 and 151, the bridge layers 30e and 30f may be left between the adjacent stacked electrodes 20.

Furthermore, also in the example illustrated in the embodiment, the second stacked electrode 20b is stacked on the first stacked electrode 20a. The embodiment is not limited thereto. For instance, the process of FIGS. 16A to 18B may be repeated to increase the stacking number of the control gates 21. Then, even if the aspect ratio of the stacked electrode 20 is increased as increasing the stacking number of the control gates 21, the bridge portions 30e and 30f may prevent the collapse.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising:
a plurality of electrodes provided on an under layer and arranged in parallel to the under layer, each of the electrodes including a plurality of first layers having conductivity and a plurality of second layers having insulation properties, the first layers being stacked in a first direction perpendicular to the under layer, and each of the second layers being provided between the first layers adjacent to each other;
a semiconductor layer piercing one of the electrodes in the first direction;
a memory film provided between the one of the electrodes and the semiconductor layer; and
a bridge portion provided between the electrodes adjacent to each other.

2. The device according to claim 1, wherein the bridge portion includes part of a second layer commonly included in the electrodes adjacent to each other.

3. The device according to claim 1, wherein the bridge portion is provided to be thicker than the second layer.

4. The device according to claim 1, wherein the bridge portion includes part of a first insulating layer provided on the first layer and part of a second insulating layer provided on the first insulating layer.

5. The device according to claim 1, wherein the bridge portion includes an insulator provided between the electrodes adjacent to each other.

6. The device according to claim 1, wherein
a plurality of bridge portions are provided between the electrodes adjacent to each other, and
the bridge portions are disposed so as not to overlap each other in the first direction.

7. The device according to claim 1, wherein
each of the first layer includes polycrystalline silicon, and
each of the second layers includes at least one of silicon oxide and silicon nitride.

8. The device according to claim 7, wherein each of the first layers includes a silicide portion.

9. The device according to claim 1, further comprising:
an insulating film provided between the electrodes adjacent to each other,
wherein the insulating film covers the bridge portion.

10. The device according to claim 9, wherein the insulating film includes at least one of silicon oxide and silicon nitride.

11. The device according to claim 1, further comprising:
a plurality of semiconductor layers extending in the first direction, each of the semiconductor layers piercing any one of the electrodes,
a joining portion electrically connecting a pair of the semiconductor layers, one of the pair piercing any one of the electrodes adjacent to each other, and the other of the pair piercing other one of the electrodes adjacent to each other.

12. A method for manufacturing a nonvolatile memory device, comprising:
forming a first stacked body including a plurality of first layers having conductivity and a plurality of second layers having insulation properties, each of the first layers and each of the second layers being alternately stacked on an under layer;
forming first slits dividing the first stacked body into a plurality of first electrodes;
embedding first sacrificial films in the first slits respectively;
forming a first bridge layer on the first electrodes and on the first sacrificial films;
selectively etching the first bridge layer to form a bridge portion between the electrodes adjacent to each other;
forming a second stacked body including first layers and second layers, each of the first layers and each of the second layers being alternately stacked on the first electrodes, the first sacrificial films, and the bridge portion;
forming second slits dividing the second stacked body into a plurality of second electrodes, and each of the second slits being in communication with any one of the first sacrificial films; and
embedding second sacrificial films in the second slits respectively.

13. The method according to claim 12, further comprising:
forming a second bridge layer on the second electrodes and the second sacrificial films; and
selectively etching the second bridge layer to form a bridge portion between the electrodes adjacent to each other.

14. The method according to claim 12, wherein
each of the first layers includes conductive polycrystalline silicon, and
each of the second layers includes at least one of silicon oxide and silicon nitride.

15. The method according to claim 12, wherein
each of the first layers includes polycrystalline silicon having conductivity, and
each of the second layers includes polycrystalline silicon having insulation properties.

16. The method according to claim 14, further comprising:
forming a silicide portion in each of the first layers,
wherein the first sacrificial films and the second sacrificial films are removed, and a metal layer is formed on inner surfaces of the first slits and inner surfaces of the second slits; and
each of the first layers and the metal layer are joined by heat treating.

17. The method according to claim 12, wherein each of the first sacrificial films and the second sacrificial films includes silicon nitride.

18. A method for manufacturing a nonvolatile memory device, comprising:
forming a first stacked body including a plurality of first layers and a plurality of second layers, each of the first layers and each of the second layers being alternately stacked on an under layer;
forming first slits dividing the first stacked body into a plurality of first electrodes;
embedding first sacrificial films inside the first slits respectively;
forming a recess in each of the first sacrificial films;
embedding an insulator in the recess to form a bridge portion between the first electrodes adjacent to each other, the insulator being different from the first sacrificial films;
forming a second stacked body having first layers and second layers, each of the first layers and each of the second layers being alternately stacked on the first electrodes, and the first sacrificial films including the bridge portions;
forming second slits dividing the second stacked body into a plurality of second electrodes, each of the second slits being in communication with any one of the first sacrificial films; and
embedding second sacrificial films inside the second slits respectively.

19. The method according to claim 18, further comprising:
forming a recess in each of the second sacrificial films; and
embedding an insulator in the recess to form a bridge portion between the second electrodes adjacent to each other, the insulator being different from the second sacrificial films.

20. The method according to claim 18, wherein
each of the first sacrificial films and the second sacrificial films includes silicon nitride, and
the insulator is silicon oxide.
